(19) United States
(12) Patent Application Publication
(10) Pub. No.: US 2025/0154655 A1
(43) Pub. Date: May 15, 2025

(54) METHOD FOR EMISSIVITY-CORRECTED PYROMETRY

(71) Applicant: AIXTRON SE, Herzogenrath (DE)

(72) Inventor: Karsten ROJEK, Mönchengladbach (DE)

(21) Appl. No.: 18/833,089

(22) PCT Filed: Jan. 19, 2023
(86) PCT No.: PCT/EP2023/051161

§ 371 Date: Aug. 20, 2024

(30) Foreign Application Priority Data
Jan. 26, 2022 (DE) 10 2022 101 809.1

(51) Int. Cl. C23C 16/52; C23C 16/458; C23C 16/46; G01J 5/00; G01J 5/80; H01L 21/66

(52) U.S. Cl. CPC C23C 16/52; C23C 16/4584; C23C 16/46; G01J 5/0007; G01J 5/806; H01L 22/12

(57) ABSTRACT

A method for coating a substrate with at least one layer. During deposition of the layer, at least one optical measuring device repeatedly determines successive measurement value pairs on the layer, each containing an emission value corresponding to the radiation power measured at a light wavelength and a reflectance value, which is also measured at a light wavelength. Actual values of a substrate temperature are calculated based on the measurement value pairs and a previously determined correction value. The actual values are used to control a temperature-control device for controlling the substrate temperature to a desired value. To improve the determination of the correction factor, during the measurement and within a plurality of measurement intervals, at least two measurement value pairs are measured and, for each of the measurement intervals, a temperature-dependent factor is determined that is used for the calculation of the correction value.

### RELATED APPLICATIONS

This application is a National Stage under 35 USC 371 of and claims priority to International Application No. PCT/EP2023/051161, filed 19 Jan. 2023, which claims the priority benefit of DE Application No. 10 2022 101 809.1, filed 26 Jan. 2022.

### FIELD OF THE INVENTION

The invention relates to a method for coating a substrate with at least one layer, wherein during the deposition of the layer at least one optical measuring device repeatedly measures successive measurement value pairs on the layer, each of which contains an emission value and a reflectance value, wherein temperature values of a substrate temperature are calculated from the measurement value pairs and a previously determined correction value. These may be used as actual values, with which a temperature control device is regulated to control the temperature of the substrate with respect to a setpoint value.

The invention further relates to an apparatus having a computing device that is programmable and programmed in such a way that correction values are calculated.

### BACKGROUND

U.S. Pat. No. 6,398,406 B1 forms the technical background of the invention. The method of emissivity-corrected pyrometry described there, also referred to as reflectivity- or reflectance-corrected or emissivity-compensated, enables non-contact optical temperature measurement during thin-film deposition with unknown and continuously changing optical properties of the measurement object. The pyrometry method for non-contact temperature measurement makes use of the relationship between the thermal radiation emitted by the hot measurement object and the temperature of the object, which is described by the known Planck's radiation equation and in practice is captured by a corresponding previous calibration, unambiguously except for the emissivity of the object. The measurement object can be any optically accessible surface in the process chamber for which monitoring or controlling the temperature is important. For this invention, the measurement object is in particular the surface of the substrate or substrates in the process chamber during the deposition process in which a semiconductor layered structure is produced with different, almost stoichiometric compounds from group III (Al, Ga, In) and nitrogen.

The state of the art is also represented by the following publication: W. G. Breiland, Technical Report SAND2003-1868 Jun. 2003, hereinafter referred to as Breiland 2003.

The state of the art also includes DE 10 2018 106 481 A1, which describes a species-related apparatus.

DE 44 19 476 C2 describes a method with which the emitted and reflected radiation from the substrate can be measured during deposition of a layer.

DE 10 2020 111 293 A1 describes emissivity-corrected pyrometry for minimizing residual oscillation.

The known method of emissivity correction is based on determining the missing, unknown emissivity by measuring the reflectance of the surface of the measurement object. The emissivity is determined using Kirchhoff's law for the case of opaque substrates where ε=1−ρ. The detection wavelength of the pyrometer is selected such that the selected substrate (in this case silicon) is opaque for the wavelength at the typical operating temperatures (T=600-1200° C.), i.e. at values in the range from 800 nm to 1000 nm. The reflectance is measured at exactly the same wavelength as the thermal emission so that the method works with sufficient accuracy. The light required for this can be provided by a laser. In practice, pyrometers do not have a sharp measuring wavelength but rather a wavelength interval (about ±10 nm, but also narrower or wider). This interval width and the effective wavelength for emissivity and reflectance measurement must match as closely as possible. The reflectance is measured by emitting light of the defined wavelength at the location of the sensor, reflecting it at the wafer surface when incident vertically and reflecting it at the same location as the pyrometer measurement to the extent possible. The reflectance is determined from the measured signal intensity of the reflected light with the aid of a previous calibration. In practice, the thermal emission of the object and the reflectance often cannot be measured simultaneously, but rather alternately with a temporal separation, so that the reflectance measurement does not interfere with the measurement of the thermal emission. See also the “lock-in technology” described in DE 44 19 476 C2 on this subject.

Two different calibration steps are required to accurately measure the temperature; performing the calibrations allows the determination of calibration parameters, which are included in the calculation of the temperature from the measurement signals. This involves the calibration of the emission measurement using a blackbody radiation source (blackbody oven, special reference sources) which creates the link between the intensity signal and the measurement temperature. During the measurement, the use of the calibration parameters determined in this way allows the “raw temperature” to be determined, which has not yet been corrected for the effect of the unknown emissivity. An independent calibration step is used to determine a calibration parameter, so that each measured reflectance signal is assigned a reflectance value from the interval 0 . . . 1. This calibration step is carried out on substrates of well-known reflectance (or emissivity in the case of opaque substrates), such as silicon immediately after the desorption process step (native oxide removal) at a known temperature and on an uncontaminated surface and before the start of layer deposition.

When depositing a thin layer with a constant growth rate, if the known method of emissivity correction is not used, a sinusoidally oscillating temperature measurement is observed, which is related to the interference effects in the transparent thin layer (Fabry-Perot oscillations). In the specific case of MOCVD deposition of GaN or AlGaN on silicon at temperatures in the range from 950 to 1100° C., the oscillations are up to +30° C. The aim of the procedure is to reduce the temperature oscillations to below ±2° C., better still ±1° C.

If the temperature measurement method described in the prior art is carried out as described, a number of errors occur, which are described below. All of these sources of error lead to the emissivity correction being carried out incompletely or artificially high. The erroneous emissivity correction manifests itself in remaining temperature oscillations (residual oscillations) whose amplitude is greater than the desired degree of error.

It has been found that the material system GaN (AlGaN) on silicon is particularly susceptible to the error sources described, because due to the values of the refractive indices for the layer and wafer material and because of the meeting of the transparent layer and opaque substrate, the measured reflectance values R oscillate between values close to zero and 0.5.

The sources of error observed can be the following errors, which also occur in practice:
Unknown exact value of the reflectance of the calibration object during reflectance calibration, so the value of the reflectance used in the calibration does not match the physical reflectance, and the reflectance values used for the emissivity correction are incorrect;
Errors in the adjustment and setup of the measuring optics;
Scattering at layer boundaries in the semiconductor layer structure when measuring the reflectance, so that part of the actually reflected light is not recorded;
Scattered radiation from hot surfaces of the process chamber, which reaches the measuring head through multiple reflections on the process chamber walls and on the wafer surface.

In the production of electronic components such as transistors for circuits for power conversion or high-frequency amplification, the control and repeatability of the deposition process and the yield of usable components per wafer are significantly limited in the embodiment of the known method on which the invention is based, because the measured wafer temperature is used for temperature control in a closed control loop. The temperature control regulates a heating device in such a way that the measured temperature constantly corresponds to a specific setpoint; the physical temperature then oscillates accordingly by the residual amplitude of the not fully corrected temperature oscillations, which represent a measurement artifact. The component has a multi-layer structure deposited on a substrate, which has a first section and a second section. Transition layers, in particular AlGaN, and buffer layers, in particular made of GaN, are deposited in the first section. An AlGaN barrier layer is deposited on the GaN buffer layer in such a way that a two-dimensional electron gas forms in the region of the layer boundary between the GaN layer and the AlGaN barrier layer. The impairment in reproducibility is related in particular to the fact that the component structure is typically composed of a sequence of functional blocks consisting of a thin AlN seed layer on the Si substrate, a transition layer sequence, a thick GaN buffer layer sequence and a relatively thin but temperature-sensitive barrier layer of AlGaN or AlInN. At the end of the buffer layer, depending on the random phase position of the residual measurement temperature oscillation, the deviation of the physical temperature from the target value from run to run or from wafer to wafer will have different values, which are translated into different values of the composition of the barrier layer, which is critical for the function of the component.

The following theoretical correction of this measurement method to compensate for the sources of error described above is given in the state of the art and is based on a mathematically deducible fact, that the effect of a series of error sources can be effectively compensated for by an additional correction value γ, so that the residual oscillations can be theoretically reduced to zero.

A similar method is described in DE 10 2020 126 597 A1.

### SUMMARY OF THE INVENTION

The starting point for the invention is the relationship between the measurement signal detected in the pyrometer due to the thermal emission of the wafer surface and the temperature of the wafer surface, wherein account is taken of the emissivity of the wafer surface, which differs from 1 due to the varying physical and optical properties during layer growth.

This relationship is described by Planck's radiation law in Wien's approximation and is presented as follows here:

$${U}_{E} = ε \cdot A \cdot {e}^{\frac{B}{T}} \qquad ( 1 )$$

$$where ε = 1 - α \cdot γ \cdot {U}_{R} \qquad ( 1 a )$$

The symbols represent the following variables:
U_{E}: Measurement signal of thermal emission from the wafer surface,
U_{R}: Measurement signal of reflectance from the wafer surface,
ε: Emissivity,
A, B: Calibration parameters, where B<0,
α: Calibration parameter for normalization of reflectance, establishes the equation between the measurement signal U_{R} and the physical reflectance R, with 0≤R≤1.
γ: Calibration parameter for the scattered light structure, which can also compensate for errors in the calibration parameter α for determining reflectance (up to the case where α=1).

The measurement signals for the thermal emission U_{E} and for the reflectance of the wafer surface U_{R} are recorded as closely together in time and space as possible. The signal that corresponds to the thermal emission is the radiation intensity, which is captured with a detector in the pyrometer and converted into a temperature measurement value by the calibration parameters A and B that were determined possibly with the help of a blackbody calibration conducted before start-up. The reflectance signal is produced by measuring the intensity of a light signal ideally having the same wavelength as the thermal emission measurement, which is emitted by the measuring unit and reflected back to the detector from the reflective wafer surface. Due to optical thin-film effects (Fabry-Perot effect), the reflectance of the wafer surface exhibits an approximately sinusoidal variation over time during deposition of the thin films. With the typical growth rates from 0.5 to 5 μm/h in GaN-on-Si processes and the wavelength of 950 nm used for the measurement, the duration of the oscillation periods is up to 10 minutes.

For the further procedure in the continuous determination of the scattered light calibration parameter γ, equation (1) is adapted correspondingly:

$${U}_{E} = A \cdot {e}^{\frac{B}{T}} \cdot ( 1 - α \cdot γ \cdot {U}_{R} ) , \qquad ( 2 )$$

$${U}_{E} = C ( T ) - C ( T ) \cdot α \cdot γ \cdot {U}_{R} \qquad ( 3 )$$

$$where$$

$$C ( T ) = A \cdot {e}^{\frac{B}{T}} . \qquad ( 4 )$$

In the specific configuration of the method for a planetary reactor with multiple single wafers, the pyrometer is attached immovably to the top of the process chamber on an optical window with visual connection to a position on the surface of the substrate carrier. For reasons of thermal averaging the substrates are rotated slowly around the centre of the reactor during the coating. A typical rotation period takes about 12 seconds, which is equivalent to five revolutions per minute. However, the rotation rate may be faster or slower. Accordingly, a measurement signal pair U_{E} and U_{R} is recorded at a certain location on the wafer that is of interest for the measurement every 12 seconds. FIGS. 1 and 2 show the configuration used. The measurement site 13 may also be a measurement zone, over which several measurements are taken. The measurement signal pair U_{E} and U_{R} corresponds to the averaged values over this zone. The site 13 or the measurement zone may be on each wafer 7 and may be located in the middle of the wafer, on the edge of the wafer, or anywhere in between. The usability of the method is dependent on the precondition that the temperature is sufficiently constant, or at least that the change in temperature is sufficiently small, for a given, relatively small number of revolution periods, that is to say multiples of 12 seconds, but at least for one revolution (12 seconds in the design used). These relatively short time intervals will be designated tᵢ in the following text. Because of the thermal inertia of the system as a whole, this precondition is satisfied during layer deposition if one refrains from deliberate heating and cooling ramps, when changing between individual layers, for example. In particular, the temperature change must not exactly correspond to or compensate for the residual oscillation in the temperature signal (the measurement artefact that is to be compensated for) in terms of frequency and phase. This is important in order to ensure that a real temperature change is not automatically corrected erroneously due to the fluctuating emissivity. It has been found that for reliable and accurate calculation of the calibration factor γ, the raw signals must be recorded over a considerably longer timeframe than those time intervals for which the wafer temperature must remain constant within a tolerance interval. These time intervals which are longer than tᵢ will be designated tₖ in the following text. The reason for this is that for the calculation of γ at least a quarter period of the thin-film oscillations, but more preferably one or more full oscillation periods must be completed in order to achieve the requisite accuracy. For the typical growth rates in the GaN process and the detection wavelength of the pyrometer used, the typical period length for a thin-film oscillation is in the range of a few minutes. The oscillation is the result of alternatingly constructive and destructive interference of the pyrometer or reflection signal in the deposited thin film during layer growth.

The problem addressed by the invention is that of improving the method described previously with regard to the accuracy of the determination of the correction value.

The problem is solved with the invention stated in the claims, wherein the subordinate claims represent not only advantageous further developments of the invention as presented in the main claim, but also represent standalone solutions to the problem.

Firstly, and essentially, it is suggested that at least two pairs of measurement values in each case be measured in a number of measurement intervals, which may be in succession, in immediate succession, in succession with time intervals and/or may also partially overlap each other, wherein each pair of measurement values contains an emission value measured with an optical measuring device and a reflectance value measured with the same or a different optical measuring device. Preferably, enough pairs of measurement values, at least two or three, are measured within a measurement interval, to enable a compensation curve to be made by a point cloud of the emission values plotted against the reflectance values. It is further proposed that a temperature-dependent factor is calculated for each of the measurement intervals. Provision may be made for the “true temperature” of the substrate, which is not measurable with the measurements described above, to change during the entire measurement time, which extends over the duration of the number of measurement intervals. The change can be up to 20° C. or more. The number of time intervals may be selected such that the “true temperature” of the substrate only changes slightly during a measurement interval, for example by a maximum of 2° C., so that the temperature within each time interval can be considered to be virtually constant. As a result, the factors calculated for each measurement interval differ from one another. In a CVD reactor, which has a susceptor rotating about an axis of rotation, on which the substrates are arranged around the axis of rotation, a specific substrate migrates at intervals of 5 to 20 seconds under a measuring point at which the pair of measurement values is measured. The duration of a measurement interval is at least long enough for the substrate to pass under the measurement point twice. The substrate preferably moves under the measuring point more than twice in the measuring interval. Layers are deposited on the substrate that have the properties that cause the emission value and the reflectance value to change periodically during the deposition due to reflections within the layer. The temporal period length is preferably significantly larger than the measurement interval. The measurement interval may be less than a quarter or a tenth of the period length. The total measurement time, i.e. the sum of the times of the measurement intervals, is preferably greater than a quarter of the period length. The total measurement time is particularly preferably greater than a period length. The measuring time may also be longer than several period lengths. The total measurement time may then be the sum of the times of all measurement intervals.

In the method, a first calculation of the emissivity-corrected wafer temperature Tᵢ is carried out for said relatively short measurement interval of one or more revolutions (time interval tᵢ). This calculation may be carried out repeatedly in several consecutive measurement intervals tᵢ, tᵢ₊₁, tᵢ₊₂, . . . . The measurement intervals may also overlap here. The measured signals U_{E} and U_{R} as well as equation (3) are included in the calculation. The result of this first calculation is a normalization factor Cᵢ(Tᵢ) for each measurement interval i, the emissivity-corrected wafer temperature Tᵢ and an estimated value for the scattered light calibration parameter γᵢ for each of the short measurement intervals i, Cᵢ(Tᵢ) and γᵢ can be determined from the plot of the measurement signals U_{E} as a function of U_{R} as in equation (3) by simple linear regression (line of best fit) or by another suitable regression or optimization method, for example. The wafer temperature Tᵢ is found from Cᵢ(Tᵢ) according to equation (4).

In a next step, the value of the calibration parameter γₖ required for the most accurate possible compensation for scattered light can be determined from these values over all measurement intervals i. The resulting high inaccuracy when determining γᵢ in the short measurement intervals i, in which the temperature is assumed to be sufficiently constant but the number of data points too small, this is compensated for by the fact that γₖ is calculated in a second calculation step using data over a significantly longer time interval tₖ>tᵢ, where tₖ corresponds to at least a quarter of the period of the oscillations, but better several full periods. This second calculation step, which serves to determine the scattered light correction parameter γₖ, may have the following embodiments.

According to a first variant of the invention, the temperature-dependent factors are used as normalization factors. In this context, the U_{E} values are normalized for each of the relatively short time intervals tᵢ with assumed constant wafer temperature with the normalization factors Cᵢ(Tᵢ) in order to obtain temperature-independent values U_{E}′ within the longer time interval tₖ. Equation (3) thus gives the temperature-independent values U_{E}′:

$${U}_{E , i}^{′} = \frac{{U}_{E , i}}{{C}_{i} ( {T}_{i} )} = 1 - α \cdot {γ}_{k} \cdot {U}_{R , i}$$

γₖ is determined from the plot of U_{E}′ over U_{R} for the longer time interval tₖ by simple linear regression or by another suitable regression or optimization method, such as that described by Breiland in the work cited above.

For each of the many measurement intervals i, a certain number of measurement value pairs are each measured over a measurement time tᵢ, for one reflectance value U_{R} and one emission value U_{E} each. The factor Cᵢ(Tᵢ) is then determined for each of the measurement intervals i in the manner described above. Inserting this in equation 5 returns an equation system whose number of equations corresponds to the number of measurements in the measurement interval i. The equation system has the two calibration factors α and γ, of which γ is unknown and via which the regression can be determined.

According to a second variant of the invention, the temperature Tᵢ is calculated from the values of Cᵢ(Tᵢ) and a fit is carried out on this temperature curve, γₖ is adjusted until the resulting measured temperature value corresponds as closely as possible to the temperature curve from the Cᵢ(Tᵢ).

First, the factors Cᵢ(Tᵢ) are determined for each measurement interval i in the manner described above. The temperature values can then be determined from the factors Cᵢ(Tᵢ). A temperature has thus been determined for each measurement interval i. A temperature T′ for each measuring point can be determined from equation 2. The temperatures T′ are different from the temperatures Tᵢ. The correction value γ can be determined by minimizing these deviations by varying the value γ.

According to a third variant of the invention, the estimated values γᵢ for the relatively shorter intervals tᵢ are averaged over the longer interval tₖ.

The method according to the invention enables in particular a continuous correction or adaptation of the correction value during the deposition of the layer. In particular, it is provided that the correction value is adjusted with each new pair of measurement values. The measurement duration or the number of measurement intervals used to determine the correction value can be kept constant or varied within specified limits. This results in an interval that varies over time, during which the measurement value pairs required to determine the correction value are calculated. The duration of the interval, i.e. the measurement duration, may be a constant value. The result of the procedure described above is a calculated temperature. This temperature may be used as an actual value in order to regulate the substrate temperature with a control circuit and a temperature control device, for example a heater, with respect to a setpoint value.

The invention also relates to an optical measuring device with which the measurement value pairs can be determined that a computing device has, with which the correction value can be calculated.

The invention also relates to a device for carrying out the method, for example a CVD reactor with a gas inlet element arranged in a reactor housing, through which a process gas that may consist of a hydride of main group III and an organometallic compound of main group IV, may be fed into a process chamber. The gas inlet element can be a central gas inlet element around which a susceptor rotates. However, the gas inlet element may also be embodied as a shower head. The susceptor, which forms the bottom of the process chamber, may be heated by a heating device. This brings the susceptor to a process temperature. The susceptor may include pockets, in each of which a substrate holder is mounted, which is mounted on a gas cushion. The substrate holder may be caused to rotate with the gas flow that generates the gas cushion. The height of the gas cushion may be varied to change the heat flow from the susceptor to the substrate holder. The heating device and the means for varying the gap height between susceptor and substrate holder form a temperature control device, which is controlled by a computing device, which may include a control device, in order to control a substrate temperature with respect to a setpoint value. In order to determine an actual value of the substrate temperature, one or more optical measuring devices may be provided, with which emission values and reflectance values can be measured. According to the invention, the computing device is programmed in such a way that a correction value is determined, with which an actual value of the substrate temperature can be calculated from the measurement value pairs using the method described above.

The correction value preferably results from a fixed number of measurement value pairs. If a new measurement value is included in the set of measurement value pairs, the oldest measurement value pair is discarded, so that the correction value is preferably only calculated from the most recent measurement value pairs.

### BRIEF DESCRIPTION OF THE DRAWINGS

In the following text, an exemplary embodiment of the method is explained in detail with reference to accompanying figures. In the drawing:

FIG. 1 is a schematic illustration of a device for carrying out the method;

FIG. 2 is a schematic illustration of the section along line II-II in FIG. 1 on the susceptor 4, on which substrates 7 are arranged, and measurement points 13, with which emission values U_{E,i} and reflectance values U_{R,i} may be measured by means of a reflectance measuring device 11 and an emissivity measuring device 12;

FIG. 3 is a schematic illustration of the structure of a multilayer structure 21 on a silicon substrate 22;

FIG. 4 shows the progression over time of the measured value of the emission U_{E} and the measured value of the reflectance U_{R}, wherein tₖ denotes a total measurement time over which measurement value pairs, each consisting of an emission value U_{E} and a reflectance value U_{R}, are measured in several measurement intervals i with a duration tᵢ;

FIG. 5 shows an example of the temporal progression of a “true temperature” over the entire measurement time tₖ, corresponding to the total duration of five measurement intervals t₁ to t₅ as a dashed line;

FIG. 6 is a schematic illustration of a method with which a temperature-dependent factor Cᵢ(Tᵢ) is obtained from at least two, in the exemplary embodiment three, measurement value pairs {U_{E}, U_{R}} of a measurement interval i by deducting the emission values U_{E} over the reflectance values U_{R} and drawing a compensation curve through the measurement points, for which the point of intersection of the compensation curve is determined with the ordinate placed through the zero point of the abscissa, the parameters α and γ are obtained from the hatched gradient triangle shown there, since α is known and Cᵢ(Tᵢ) is obtained from the y-axis distance, γ can be calculated;

FIG. 7 shows the schematic representation according to FIG. 6 to illustrate a first exemplary embodiment, in which all measurement values of all measurement intervals i are shown in a diagram, to illustrate that the measurement points of various measurement intervals i lead to compensation straight lines with various gradients and various intersection points with the ordinate, parameter α results from the hatched gradient triangle shown there;

FIG. 8 shows the representation according to FIG. 6, in which all measured values of all measurement intervals are shown in a diagram, but instead of an emission value U_{E} a normalized emission value U_{E}′ is used, calculated by dividing the measured emission value U_{E} by a normalization factor Cᵢ(Tᵢ) and drawing a compensation curve through the point cloud obtained in this way, which intersects the ordinate at the value 1 and whose slope is the product of a calibration parameter α and a correction value γ;

FIG. 9 shows the schematic representation according to FIG. 5 to illustrate a second embodiment, but instead of showing the progression of the “true temperature” of the substrate, represents the temperatures Tᵢ calculated from the factors Cᵢ(Tᵢ) for each measurement interval i according to FIG. 6;

FIG. 10 shows a representation according to FIG. 9, wherein the calculated temperature Tᵢ is assigned in the middle of each time interval, and a connecting curve through the calculated temperatures Tᵢ is shown, which may also consist of a polygon, and the distances of the temperature Tₙ′ calculated for each measuring point n from the calculated temperature Tᵢ of the measurement interval i are shown, which are to be minimized in an optimization process;

FIG. 11 shows a flow chart of the method.

### DETAILED DESCRIPTION

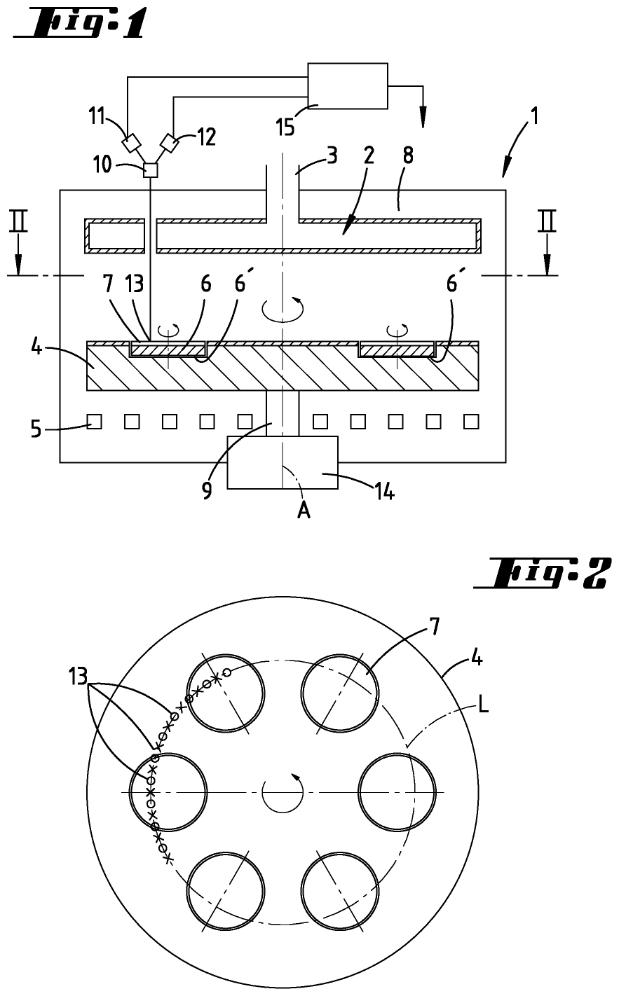

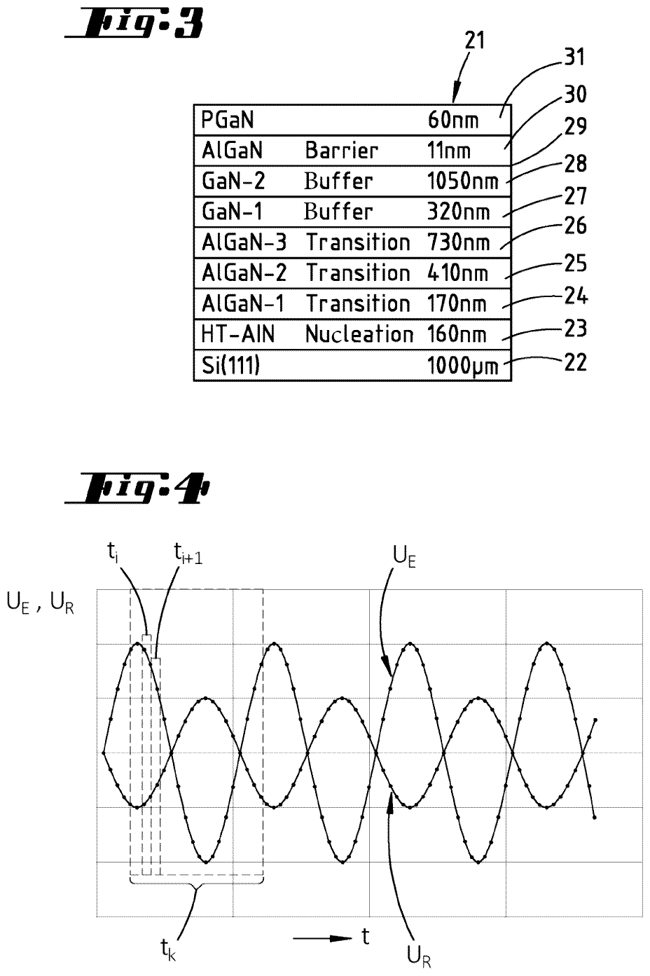

The CVD reactor shown in FIGS. 1 and 2 has a reactor housing 1, a heating device 5 arranged therein, a susceptor 4 arranged above the heating device 5, and a gas inlet element 2 for introducing, for example, TMGa, TMAI, NH₃, AsH₃, PH₃ and H₂.

The susceptor 4 is driven in rotation about a vertical axis of rotation A with the aid of a rotary drive device 14. For this purpose, a drive shaft 9 is connected on the one hand to the rotary drive device 14 and on the other hand to the underside of the susceptor 4. Substrates 7 lie on the horizontal surface of the susceptor 4 facing away from the heating device 5. Substrate holders 6 are provided, on which the substrates 7 lie. The substrates 7 are located radially outside the axis of rotation A and are held in position by substrate receptacles.

Two measuring devices may be provided. An emissivity measuring device 12 may be formed by a pyrometer. A reflectance measuring device 11 may also be formed by a pyrometer. A beam splitter 10 may be provided, with which an input beam can be divided between the two measuring devices 12, 11. The beam path is incident on the substrate 7 at a measuring point 13. FIG. 2 suggests that the measuring point 13 migrates over all of the substrates 7 during a rotation of the susceptor 4.

FIG. 3 shows a multi-layer structure 21 which is deposited one layer after the other in a plurality of successive coating steps in a coating process. First, a nucleation layer 23 of AlN or InN is deposited on the silicon substrate 22. A first AlGaN layer 24 is then deposited on the nucleation layer 23, followed by a second AlGaN layer 25 and a third AlGaN layer 26. The three AlGaN layers 24 to 26 form transition layers. The aluminium content of the transition layers may decrease incrementally.

A first buffer layer 27 of GaN is then deposited on the transition layers 24 to 26. The layer may be C-doped. A second buffer layer 28, also of GaN, which may be undoped, is then deposited on the first buffer layer 27.

When one of the layers 23 to 31 is deposited on the substrate 22, measurement value pairs {U_{E,n}, U_{R,n}} are measured at one measurement point 13 each with the aid of the reflectance measuring device 11 and the emissivity measuring device 12 on the top of the substrate 7 facing the process chamber 8. These pairs of measured values are stored in a storage device of a computing device 15. The two measuring devices 11 and 12 may be arranged in a common measuring head, and the optical measuring device designed in this way may include a computing device 15. The computing device 15 may be accommodated in a housing arranged outside the reactor housing 1. A light source may also be accommodated there, the light of which is guided to the measuring head with a light guide. The measuring head may also have a further light guide, with which light is guided to the housing 1, where an optical measuring device is arranged, which performs the function of both the reflectance measuring device and that of the emissivity measuring device.

The current temperature T_{C} of the substrate 7 may be determined according to Planck's law of radiation. For the sake of simplicity, Wien's approximation is used for this purpose below:

$${U}_{E} = ε \cdot A \cdot {e}^{\frac{B}{T}} \qquad ( 1 )$$

$$where$$

$$ε = 1 - α \cdot γ \cdot {U}_{R} \qquad ( 1 a )$$

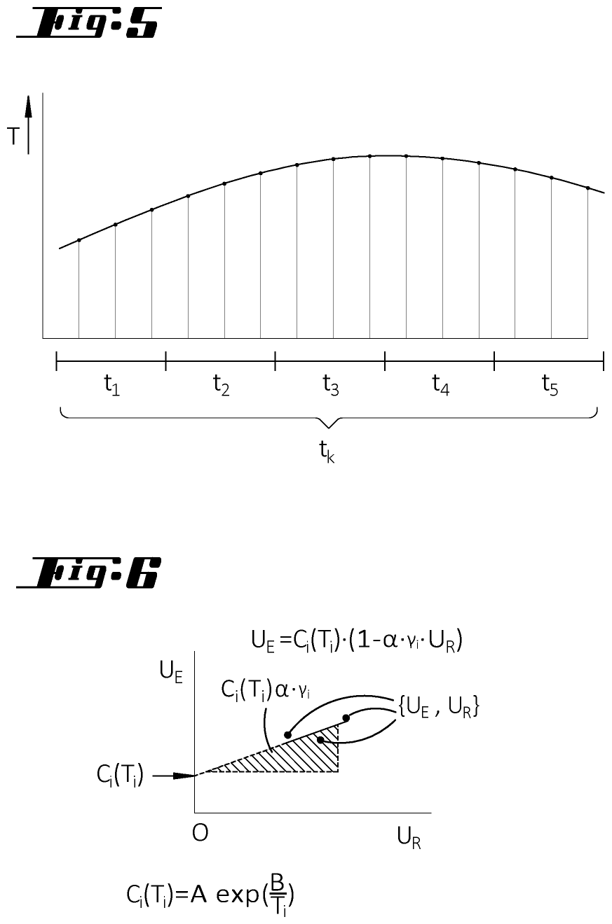

FIG. 4 schematically shows the progression over time of both the emission value U_{E} and the reflectance value U_{R}. Due to the reflections inside the deposited layer, the measurement signal oscillates with increasing layer thickness, i.e. with increasing time t.

In order to compensate for residual oscillations due to scattered light effects or the like, the calibration parameter γ referred to above is inserted, yielding the following relationship:

$${U}_{E} = A \cdot {e}^{\frac{B}{T}} \cdot ( 1 - α \cdot γ \cdot {U}_{R} ) , \qquad ( 2 )$$

$${U}_{E} = C ( T ) - C ( T ) \cdot α \cdot γ \cdot {U}_{R} \qquad ( 3 )$$

where the following factor plays a role that is significant for the invention:

$$C ( T ) = A \cdot {e}^{\frac{B}{T}} . \qquad ( 4 )$$

In the method according to the invention, measurement value pairs are obtained during the deposition of one of the layers represented in FIG. 3 and in particular one of the layers 23 to 28 during a time tₖ. FIG. 5 shows, by way of example, a “true temperature” progression of a temperature of the substrate which is not constant over time, which rises slightly and falls slightly at a later time. The total time tₖ, during which the measurement is carried out, is divided into a plurality of measurement intervals i with measurement times tᵢ, in the exemplary embodiment t₁, t₂, t₃, t₄ and t₅. During each measurement interval i or measurement times t₁, t₂, t₃, t₄ and t₅, three pairs of measurement values {U_{E,1}, U_{R,1}} are obtained, each pair of measurement values containing an emission value U_{E} and a reflectance value U_{R}.

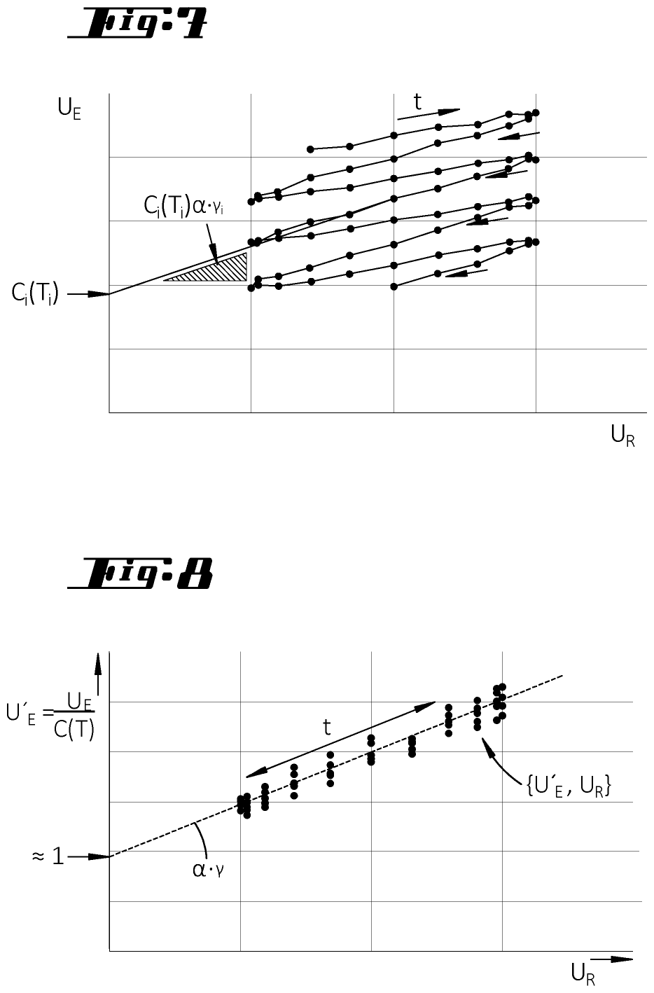

FIG. 6 shows a representation in which the measurement value pairs {U_{E}, U_{R}} of one of the measurement intervals tᵢ are shown as measurement points in a coordinate system U_{E} versus U_{R}. Equation 2 shows that the correction value γ embodies the unknown contribution to the gradient of a straight line. From equation 3, it is apparent that the factor C(T) can be determined by the point of intersection of the compensation curve through the ordinate of the coordinate system.

A correction value γᵢ assigned to the measurement interval i and a factor Cᵢ can thus be found for each measurement interval i by means of a linear regression. A temperature Tᵢ of each measurement interval i can in turn be obtained from the factor Cᵢ according to equation 4 (see FIG. 9).

If, as shown in FIG. 7, all measurement points of all measurement intervals i were represented in a diagram, compensation curves with different gradients and different intersection points with the ordinate would form. FIG. 7 shows that there are individual correction values γᵢ and factors Cᵢ for each of the measurement intervals i based on the temperature profile shown in FIG. 5.

In order to be able to evaluate the relationships between the emission values U_{E} and reflectance values U_{R} in a joint representation, according to a first exemplary embodiment of the invention, the emission value U_{E} is normalized by dividing the measured emission value U_{E} by the factor Cᵢ of the respective measurement interval i. The normalized emission values U_{E,i}′ obtained in this way for all measurement value pairs are shown in FIG. 8. The formal relationship between the normalized emission value U_{E}′, a unified correction value γ and the reflectance values U_{R,n} and the emission values U_{E,n} is as follows:

$${U}_{E}^{′} = \frac{{U}_{E , n}}{{C}_{i} ( {T}_{i} )} = 1 - α \cdot {γ}_{k} \cdot {U}_{R , n} . \qquad ( 5 a )$$

The point cloud shown in FIG. 8 can thus be used to represent the linear relationship resulting from equation 5a. The correction value γ may be determined from the gradient of the compensation curve, which is obtained according to FIG. 4 from measurement values recorded over at least one period length, but which is divided into several measurement intervals.

This correction value γ is used to calculate the temperatures T from the relationships according to equation 2 or equation 3, which are used in the regulation as the actual value of a substrate temperature, for example in order to deposit one of the layers shown in FIG. 3, wherein U_{E} and U_{R} are the current values of the emission value and the reflectance value, respectively.

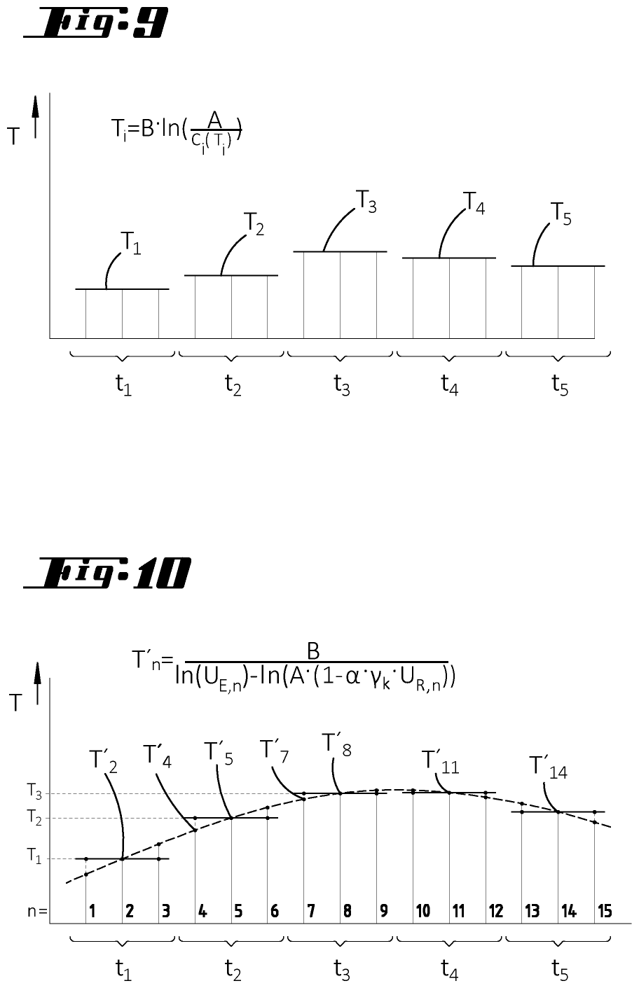

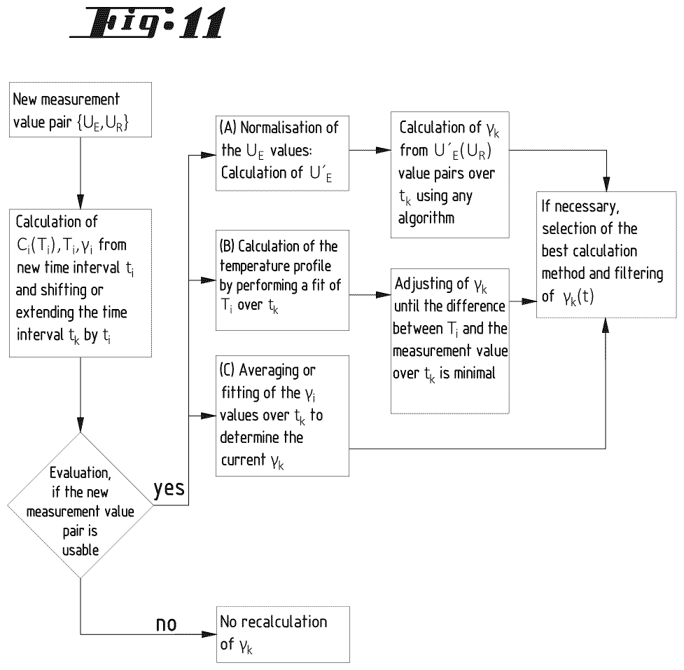

A second exemplary embodiment of the invention is explained with reference to FIGS. 9 and 10.

FIG. 9 shows a representation similar to FIG. 5, but instead of the “true temperature”, which is technically difficult to measure, the temperatures Tᵢ that can be calculated from the method step explained with reference to FIG. 6 are plotted. The temperatures Tᵢ are determined directly from the factor Cᵢ as follows:

$${T}_{i} = \frac{B}{ln ( \frac{{C}_{i} ( {T}_{i} )}{A} )} . \qquad ( 6 )$$

Following this, a compensating curve is drawn by the temperatures Tᵢ approximately through the temporal midpoints of the measurement intervals i. This compensating curve is shown in FIG. 10 as a dashed line between the midpoints of the measurement intervals i. It is evident that the mean temperatures Tᵢ of the measurement intervals i calculated with Cᵢ(Tᵢ) deviate from the temperatures Tₙ′ calculated individually according to the following equation.

$${T}_{n}^{′} = \frac{B}{ln ( {U}_{E , n} ) - ln ( A \cdot ( 1 - a \cdot γ \cdot {U}_{R , n} ) )} \qquad ( 7 )$$

By means of an optimization calculation, for example as follows:

$$\frac{d}{d γ} \sum {( {T}_{n}^{′} - {T}_{i} )}^{2} \qquad ( 8 )$$

a value can be calculated for the correction value γ by varying the correction value γ in equation 7 until the resulting measured temperature value T/matches the temperature curve from Cᵢ(Tᵢ) as closely as possible.

In the exemplary embodiment shown in FIG. 10, a polygon may also be plotted through the calculated temperatures Tᵢ as the compensation curve. In other embodiments, an exponential curve, a sinusoidal curve, or a combination of such curves may be used.

According to a third exemplary embodiment of the invention, individual correction values γᵢ are first calculated for each measurement interval i, as described above with reference to FIG. 6. A mean value is then calculated from these correction values γᵢ.

Further embodiments in connection with the methods of the first, second or third exemplary embodiments described above may have the following properties:

Besides the calculation of Cᵢ(Tᵢ) and Tᵢ from a time interval tᵢ for a given data point U_{Ei} or U_{Ri}, Cᵢ(Tᵢ) and Tᵢ can also be determined from two or more time intervals tᵢ, tᵢ₊₁, . . . , that lie before and after a specific measurement value pair. The valid values C; (Tᵢ) and Tᵢ are then the mean values from the calculation over several time intervals.

In a preferred variant of the invention or the exemplary embodiments, the number of measurement intervals or the measurement duration is kept constant. When calculating the correction value γ in this variant, only the most recent measurement value pairs are used. If the set of measurement value pairs is supplemented by a new measurement value pair, the oldest measurement value pair in each case is removed from the set. With this method, a measuring window that varies over time is established, during which the measurement values needed for the correction value are determined. The correction value γ is updated with each measurement.

In addition, a sliding fit may be applied through all Cᵢ(Tᵢ) (possibly with a weighting on the most recent measurement data) to enable the values used for the calculation of U_{E}′ to be determined as accurately as possible. Depending on the type of temperature change to be expected, this fit may be linear, polynomial, exponential, sinusoidal or a combination of these functions. The appropriate function may also be selected automatically depending on the signal form.

In order to reduce the noise of the data originating from the calculation over the time intervals tᵢ, particularly erroneous data can be rejected.

Here, both Tᵢ and Yᵢ can be used as a figure of merit.
i. Tᵢ can be compared to the mean temperature in the time interval tₓ where tᵢ>tₓ>tₖ (possibly measured with an incorrect γ value). If the difference is too large, for example greater than 10° C., then the corresponding data point is rejected and not used for further calculations. The temperature comparison can also be made with the maximum temperature measured in time interval tₓ, which is typically closer to the real temperature than the mean value.
ii. It is usually known from experience in which range γₖ can lie for a given system and a given process. For example, this can be the value range 0.95 to 0.98. Value pairs with a γᵢ outside this range can be rejected. If there is no empirical value, the comparison between the classically calculated γ_{k,class}. without taking temperature changes into account and the γₖ calculated as described here can return the maximum allowed offset |γ_{k,class.}−γₖ| from γᵢ. The allowed offset may also be a multiple of |Y_{k,class.}−γₖ|.

When performing a fit over the longer time interval tₖ, values with a particularly large deviation can be rejected. This is possible in the first, second and third embodiments.

Data from data points with minimum and maximum reflection (or maximum and minimum emission signal) can be excluded from the calculation. Due to the small change in reflectance and emissivity, these data points are particularly susceptible to noise.

A further possibility of improving noise is the use of several measurement locations or measurement zones (FIG. 2). In general, a measuring zone must be selected sufficiently small, since the residual oscillation of the temperature signal is averaged out due to different layer thicknesses over a wafer, but the resulting signal is incorrect. However, the γₖ calculation can be carried out over several measurement zones or locations at the same time. These measurement zones may be on the same wafer or on several wafers. Another advantage is that more frequent recalculations than once per revolution are possible. Since it is to be expected that γₖ is constant for all measurement zones and locations if layer growth is sufficiently homogeneous, the mean value of γₖ from the various measurement zones can be taken as a valid value.

As described, it is possible for γₖ to vary over the course of the process. With the method presented here, γₖ can be adjusted continuously. However, a sudden change in γₖ is not to be expected. Therefore, the continuous change of γₖ can be smoothed with a suitable filter method (e.g. a low-pass filter).

In the method of the third exemplary embodiment, a continuous fit may also be used instead of a simple averaging in order to predict the change in γₖ. This fit may be linear, polynomial, exponential, sinusoidal or a combination of these functions depending on the expected change. The appropriate function may also be selected automatically depending on the signal form.

This procedure may also be used in the methods of the first and second exemplary embodiments. In such cases, γₖ is replaced with a time-dependent function γₖ(t).
i. In the case of a temperature step in the process or a pause in growth, this must be taken into account in the temporal function γₖ(t); for example, by deleting the values that are not to be used and shifting the time axis so that there is no longer a pause in the data.

According to the method of the first exemplary embodiment, the y-intercept of the linear fit of the data U_{E}′(U_{R}) is ideally equal to 1. If the deviation is greater than a value to be defined, the specific value for γₖ can be declared invalid. Then the value for γₖ used previously is to be used further.

A γₖ can be specified at the beginning of the process if not enough data is available. This may originate, for example, from empirical values or the previous process result. This value is then the basis for rejecting, serves as the basis for a filter or serves as the starting point for a fit.

In the case of a large temperature change (for example between two layers), the data U_{E} (U_{R}) cannot be used. This can be done automatically by rejection of the data points or manually by recipe control and/or detection of the change in the temperature setpoint. A continuous calculation of γₖ with exclusion of this data is possible with the data before and after the temperature change.

γₖ can also be calculated by all three methods simultaneously. A valid γₖ can be selected using the methods described previously. If there are several valid values, an averaging or a previously specified prioritization of the methods can define the value.

Since both γᵢ and Tᵢ (and thus C (Tᵢ)) are variable over time, an iterative function might also be used in the method of the second exemplary embodiment to determine the optimal (temporal) profile of γᵢ and Tᵢ. γₖ could then be determined from this time profile.
a. The iterative procedure may be such that Tᵢ is recalculated after each γₖ Or γₖ(t) calculation, taking γₖ Or γₖ(t) into account.
b. The progression of C (Tt) from the method of the second exemplary embodiment can be used to carry out an optimized calculation according to the method of the first or third embodiments. The progression of C (Tt) is then taken into account in the linear fit.

The length of the time interval tₖ may be determined automatically in order to map exactly one or a multiple of the oscillation period.

The error in the gradient caused by the temperature change can be determined from the difference, depending on whether U_{E} or U_{R} is rising or falling (over a whole oscillation period). This allows the calculation to be corrected in each tᵢ interval.

The temperature change can be estimated from the difference between Tᵢ and Tᵢ₊₁. With a constant temperature change, Tᵢ and Tᵢ₊₁ will be shifted in the same direction if the calculation is not made at the reversal point of U_{E} and U_{R}. This can then be used iteratively to correct the calculation of Tᵢ and Tᵢ₊₁.

The preceding notes are intended to serve as an explanation of the inventions reported as a whole in the application, which further develop the state of the art at least with the following feature combinations, also each on their own merits, wherein two, several or all of said feature combinations may also be combined, specifically:

A method that is characterized in that at least two measurement value pairs {U_{E,n}, U_{R,n}} are measured during a measurement period within a multiplicity k of measurement intervals tᵢ and a temperature-dependent factor Cᵢ(Tᵢ) is determined for each of the measurement intervals tᵢ, which factor is used for the calculation of the correction value γ.

A method that is characterized in that the factor Cᵢ(Tᵢ) is a product of a first calibration parameter A with the value of the exponential function of a quotient of a second calibration parameter B and a temperature Tᵢ.

A method that is characterized in that the factor Cᵢ(Tᵢ) is obtained by a regression of the emission values U_{E} each plotted against the reflectance values U_{R} or using an optimization method.

A method that is characterized in that normalized emission values U_{E}′ are formed from the emission values U_{E} recorded in at least some of the measurement intervals by dividing by the respective factor Cᵢ(Tᵢ), and the correction value γ is calculated by a regression over the normalized emission values U_{E}′ plotted against the reflectance values U_{R} or by an optimization process.

A method that is characterized in that the correction value γ is formed from the gradient of a compensation curve through the normalized emission values U_{E}′.

A method that is characterized in that a correction value γ is obtained by adapting temperature values Tᵢ obtained from the factors Cᵢ(Tᵢ) to temperature values Tᵢ calculated from the respective measurement value pairs {U_{E,n}, U_{R,n}}.

A method that is characterized in that a correction value γᵢ is determined for each of the measurement intervals tᵢ and a mean value is formed from these correction values γᵢ over the measurement period.

A method that is characterized in that the emission value U_{E} and the reflectance value U_{R} change periodically during the deposition of layers 23 to 31 or a multilayer structure 21 consisting of several layers 23 to 31 with a period length, wherein the temporal duration of a measurement interval tᵢ is less than a quarter or a tenth of the period length, and that the total duration of all measurement intervals tᵢ is greater than a quarter of the period length or a multiple of the period length.

A method that is characterized in that the measurement duration or the number of measurement intervals tᵢ used to determine the correction value γ is kept constant and/or that the correction value γ changes over time.

A method that is characterized in that the correction value γ is continuously optimized during the deposition of one or more layers on the substrate and/or that the correction value γ is updated with each newly determined measurement value pair {U_{E,n}, U_{R,n}}, and/or that a constant number or a number of measured value pairs that varies within a predetermined range is used to calculate the correction value γ.

A method that is characterized in that the temperature value T_{C} is an actual value with which a temperature control device 5, 6′ for controlling the temperature of the substrate 22 is regulated with respect to a setpoint s.

A measuring device that is characterized in that the computing device 15 is programmed in such a way that the correction value γ is determined according to a method according to any one of the above methods.

A device that is characterized in that the measuring device is embodied according to the above measuring device.

All disclosed features are essential to the invention (by themselves, but also in combination with one another). In the disclosure of the application the disclosure content of the associated/attached priority documents (copy of the previous application) is hereby also included in its entirety, also for the purpose of including features of these documents in claims of the present application. The subclaims, even without the features of a referenced claim, characterize with their features independent inventive developments of the prior art, in particular for making divisional applications on the basis of these claims. The invention specified in each claim can additionally have one or more of the features specified in the above description, in particular with reference numbers and/or specified in the list of reference numbers. The invention also relates to configurations in which individual features mentioned in the above description are not implemented, in particular if they are clearly superfluous for the respective intended use or can be replaced by other technically equivalent means.

### LIST OF REFERENCE SYMBOLS

1 Reactor housing
2 Gas inlet element
3 Gas supply line
4 Susceptor
5 Heating device
6 Substrate holder
6 Gas cushion
7 Substrate
8 Process chamber
9 Drive shaft
10 Beam splitter
11 Reflectance measuring device
12 Emission measuring device
13 Measuring point
14 Rotary drive device
15 Computing device
21 Multilayer structure
22 Substrate
23 Nucleation layer
24 Transition layer
25 Transition layer
26 Transition layer
27 Buffer layer
28 Buffer layer
29 Boundary layer, two-dimensional electron gas
30 Barrier layer
31 Cover layer
γ Correction value
γᵢ Correction value of a measurement interval
λ Wavelength
α Calibration parameter
A Axis of rotation
A Calibration parameter
B Calibration parameter
U_{E} Emission value
U_{E}′ Normalized emission value
U_{R} Reflectance value
U_{E,n} Emission value
U_{R,n} Reflectance value
T_{C} Corrected temperature, temperature actual value
T_{M} Measurement temperature
T_{S} Temperature setpoint
tᵢ Time interval
i Index of a measurement interval
n Index of a measurement pair
k Number of measurement intervals
tₖ Total measurement time
S Setpoint

What is claimed is:

1. A method for coating a substrate (22) with at least one layer (23 to 31), the method comprising:
depositing the at least one layer (23 to 31) on the substrate (22);
while depositing the at least one layer (23 to 31), repeatedly measuring by at least one optical measuring device (11, 12) successive measurement value pairs {U_{E,n}, U_{R,n}} on the at least one layer (23 to 31), each measurement value pair containing an emission value U_{E} corresponding to a radiation power measured at a light wavelength, and a reflectance value U_{R}, which is also measured at the light wavelength;
calculating temperature values T_{C} of the at least one layer (23 to 31) on the substrate (22) from the measurement value pairs {U_{E,n}, U_{R,n}} using equations:
$${U}_{E} = A \cdot {e}^{\frac{B}{T}} \cdot ( 1 - α \cdot γ \cdot {U}_{R} ) and$$
$${U}_{E} = C ( T ) - C ( T ) \cdot α \cdot γ \cdot {U}_{R} ,$$
wherein:
A is a first calibration parameter,
B is a second calibration parameter in which B<0,
α is a reflectance normalization calibration parameter which relates the reflectance value U_{R} and a physical reflectance R, where 0≤R≤1,
γ is a correction value, and
C(T) is a temperature-dependent factor that satisfies
$$C ( T ) = A \cdot {e}^{\frac{B}{T}}$$
wherein at least two of the measurement value pairs {U_{E,n}, U_{R,n}} are each measured during a measurement duration within a plurality of measurement intervals tᵢ, 1≤i≤k;
determining the temperature-dependent factor Cᵢ(Tᵢ) for each of the measurement intervals tᵢ; and
calculating the correction value γ based on the temperature-dependent factor Cᵢ(Tᵢ) determined for each of the measurement intervals tᵢ.

2. (canceled)

3. The method of claim 1, wherein for each of the measurement intervals tᵢ, the temperature-dependent factor Cᵢ(Tᵢ) is determined by a regression of the emission values U_{E} measured within the measurement interval tᵢ, and plotted against the reflectance values U_{R} measured within the measurement interval tᵢ.

4. The method of claim 1, further comprising forming normalized emission values U_{E,n}′ from the emission values U_{E,n} recorded in at least some of the measurement intervals tᵢ by, for each of the at least some of the measurement intervals tᵢ, dividing each of the emission values U_{E,n} measured within the measurement interval tᵢ by the respective temperature-dependent factor Cᵢ(Tᵢ) determined for the measurement interval tᵢ in accordance with
$${U}_{E , n}^{′} = \frac{{U}_{E , n}}{{C}_{i} ( {T}_{i} )} = ( 1 - α \cdot γ \cdot {U}_{R , n} )$$

5. The method of claim 4, wherein the correction value γ is formed from a gradient of a compensation curve through the normalized emission values U_{E,n}′.

6. The method of claim 1, wherein the correction value γ is obtained by adapting first temperature values Tᵢ to second temperature values Tᵢ′,
wherein each of the first temperature values Tᵢ is calculated from the respective temperature-dependent factors Cᵢ(Tᵢ) in accordance with Tᵢ=B, and
wherein each of the second temperature values Tᵢ′ are calculated from the respective measurement value pairs {U_{E,n}, U_{R,n}}, in accordance with Tᵢ′=B.

7. The method of claim 1, wherein an interval-specific correction value (γᵢ) is determined for each of the measurement intervals tᵢ, and an average value is formed from the interval-specific correction values (γᵢ).

8. The method of claim 1,
wherein respective time progressions of the emission values U_{E} and the reflectance values U_{R} are periodic with a period length,
wherein a temporal duration of each of the measurement intervals tᵢ is less than a quarter of the period length, and
wherein a total duration of all of the measurement intervals tᵢ is greater than the quarter of the period length or a multiple of the period length.

9. The method of claim 1, wherein at least one of:
the measurement duration or a number of measurement intervals tᵢ used to determine the correction value γ is kept constant; or
the correction value γ changes over time.

10. The method of claim 1, wherein at least one of:
the correction value γ is optimized continuously during the deposition of the at least one layer (23 to 31) on the substrate (22),
the correction value γ is updated with each newly determined measurement value pair {U_{E,n}, U_{R,n}} or
a constant number of the measurement value pairs {U_{E,n}, U_{R,n}} or a number of the measurement value pairs {U_{E,n}, U_{R,n}} that varies within a predetermined range is used to calculate the correction value γ.

11. The method of claim 1, further comprising utilizing the temperature values (T_{C}) to regulate a temperature control device (5, 6′) for controlling a temperature of the substrate (22) with respect to a setpoint s.

12. A measuring device, comprising:
one or more optical measuring devices (11, 12) configured to repeatedly measure successive measurement value pairs {U_{E,n}, U_{R,n}} in an apparatus for depositing at least one layer (23 to 31), each measurement value pair {U_{E,n}, U_{R,n}} containing an emission value U_{E} and a reflectance value U_{R}; and
a computing device (15) configured to calculate temperature values T_{C} of a surface of the at least one layer (23 to 31) using a correction value γ, wherein the computing device (15) is programmed to determine the correction value γ in accordance with the method of claim 1.

13. A device for depositing at least one layer (23 to 31) on a substrate (22), the device comprising:
a reactor housing (1);
a process chamber (8) formed within the reactor housing (1);
a gas inlet element (2) arranged in the reactor housing (1), through which process gases are fed into the process chamber (8);
a susceptor (4) having a surface facing towards the process chamber (8), wherein the substrate (22) is arranged on the surface of the susceptor (4);
a heating device (5) for heating the susceptor (4);
one or more optical measuring devices (11, 12) for repeatedly measuring an emission value U_{E} and a reflectance value U_{R} of the at least one layer (23 to 31) of the substrate (22) facing towards the process chamber (8);
a control device for regulating a temperature of the substrate (22) using the emission values U_{E} and reflectance values U_{R} measured by the at least one or more optical measuring devices (11, 12); and
a computing device (15) configured to calculate temperature values T_{C} of the at least one layer (23 to 31) using a correction value γ, wherein the computing device (15) is programmed to determine the correction value γ in accordance with the method of claim 1.

14. (canceled)
